(19) United States
(12) Patent Application Publication
(10) Pub. No.: US 2024/0186208 A1
(43) Pub. Date: Jun. 6, 2024

(54) METHOD, STRUCTURE, AND MANUFACTURING METHOD FOR EXPANDING CHIP HEAT DISSIPATION AREA

(71) Applicants: ADVANTEST CORPORATION, Tokyo (JP); TOKYO INSTITUTE OF TECHNOLOGY, Tokyo (JP)

(72) Inventors: Shinji SUGATANI, Saitama (JP); Takayuki OHBA, Kanagawa (JP)

(21) Appl. No.: 18/470,458

(22) Filed: Sep. 20, 2023

(30) Foreign Application Priority Data
Dec. 2, 2022 (JP) 2022-193837

(51) Int. Cl. H01L 23/367; H01L 21/56; H01L 23/29; H01L 23/31; H01L 23/427; H01L 23/544; H01L 25/00; H01L 25/065

(52) U.S. Cl. CPC H01L 23/367; H01L 21/56; H01L 23/291; H01L 23/3128; H01L 23/3135; H01L 23/427; H01L 23/544; H01L 25/0655; H01L 25/50; H01L 24/13

(57) ABSTRACT

Provided is a semiconductor device, comprising: a semiconductor chip where a circuit is formed on a side of a first surface of a chip substrate and a transition structure is integrated on a side of a second surface which is opposite to the first surface of the chip substrate, wherein the transition structure is obtained by causing a ratio of a substrate material of a chip substrate body to be less than a ratio of the substrate material on the side of the first surface and adding a thermal conductive material which has a higher thermal conductivity than the substrate material; and a thermal conductor which is joined to the second surface of the semiconductor chip and has a higher thermal conductivity than the substrate material.

The contents of the following patent application(s) are incorporated herein by reference:
NO. 2022-193837 filed in JP on Dec. 2, 2022

### BACKGROUND

### 1. Technical Field

The present invention relates to a method, a structure, and a manufacturing method for expanding a chip heat dissipation area.

### 2. Related Art

Patent document 1 describes, “Thermal conductive fiber 2 . . . may be . . . copper . . . . As elastic fabric 2 is closer to the adhesive boundary with the heatsink 8, it is more likely to shrink to be dense during temperature dropping of the thermally conductive fiber 2 and more likely to expand to be sparse during temperature rising, which contributes to relaxing the thermal stress”. Patent document 2 describes, “The cooling structure X includes a heatsink 10, a thermal conductive portion 20, and a sealant 30, and is attached on an electronic component such as a semiconductor element 40 . . . . The thermal conductive portion 20 consists of a mesh member 21 and a liquid metal 22 which is carried by this”. Non-Patent Document 1 discloses that a heatsink and a lid are in contact with a semiconductor via the TIM (Thermal Interface Materials).

### PRIOR ART DOCUMENT

### Patent Document

Patent Document 1: Japanese Patent Application Publication No. 2005-232207.
Patent Document 2: Japanese Patent Application Publication No. 2003-332505.

### Non-Patent Document

Non-Patent Document 1: Xiaopeng Huang, Vadim Gektin, LIDDED VS. LIDLESS: A THERMAL STUDY, Proceedings of the ASME 2018 International Technical Conference and Exhibition on Packaging and Integration of Electronic and Photonic Microsystems InterPACK2018, August 27-30, 2018, San Francisco, CA, USA.

### BRIEF DESCRIPTION OF THE DRAWINGS

FIG. 1 shows a configuration of a semiconductor device 100 according to the present embodiment.

FIG. 2 shows a perspective view of the first example of a transition structure 126 according to the present embodiment.

FIG. 3A shows a perspective view of the second example of the transition structure 126 according to the present embodiment.

FIG. 3B shows a cross-sectional view of the second example of the transition structure 126 according to the present embodiment.

FIG. 4 shows an example of a layer structure formed between a substrate material and a thermal conductive material in a transition structure 400.

FIG. 5 shows a configuration of a vapor chamber 500.

FIG. 6A shows the stage of manufacturing a semiconductor chip 120 in the manufacturing method of the semiconductor device 100 according to the present embodiment.

FIG. 6B shows the stage of forming a trench 610 in the manufacturing method of the semiconductor device 100 according to the present embodiment.

FIG. 6C shows the stage of filling a thermal conductive material 620 in the manufacturing method of the semiconductor device 100 according to the present embodiment.

FIG. 6D shows the stage of forming the transition structure 126 in the manufacturing method of the semiconductor device 100 according to the present embodiment.

FIG. 7A shows the stage of mounting the semiconductor chip 120 on a package substrate 110 in the first embodiment of the manufacturing method of the semiconductor device 100 according to the present embodiment.

FIG. 7B shows the stage of joining the semiconductor chip 120 and a thermal conductor 130 in the first embodiment of the manufacturing method of the semiconductor device 100 according to the present embodiment.

FIG. 7C shows the stage of forming a first underfill structure 160 in the first embodiment of the manufacturing method of the semiconductor device 100 according to the present embodiment.

FIG. 8A shows a structure of a carrier substrate 800 in the second embodiment of the manufacturing method of the semiconductor device 100 according to the present embodiment.

FIG. 8B shows the stage of forming a thermal conductive layer 810 in the second embodiment of the manufacturing method of the semiconductor device 100 according to the present embodiment.

FIG. 8C shows the stage of joining the thermal conductive layer 810 and the semiconductor chip 120 in the second embodiment of the manufacturing method of the semiconductor device 100 according to the present embodiment.

FIG. 8D shows the stage of separating the thermal conductive layer 810 and the semiconductor chip 120 from the carrier substrate 800 in the second embodiment of the manufacturing method of the semiconductor device 100 according to the present embodiment.

FIG. 9A shows the stage of joining the semiconductor chip 120 and the first thermal conductor component 510 in the method of joining the semiconductor chip 120 and the vapor chamber 500.

FIG. 9B shows the stage of injecting a coolant fluid 540 into the first thermal conductor component 510 in the method of joining the semiconductor chip 120 and the vapor chamber 500.

FIG. 9C shows the stage of joining the first thermal conductor component 510 and the second thermal conductor component 520 in the method of joining the semiconductor chip 120 and the vapor chamber 500.

FIG. 10A shows the stage of mounting the first semiconductor chip 1010 and the second semiconductor chip 1015 on the package substrate 110 in the manufacturing method of a semiconductor device 1000 including a plurality of semiconductor chips.

FIG. 10B shows the stage of aligning the heights of the first transition structure 1020 and the second transition structure 1025 in the manufacturing method of the semiconductor device 1000 including a plurality of semiconductor chips.

FIG. 10C shows the stage of joining the thermal conductor 130 to the first semiconductor chip 1010 and the second semiconductor chip 1015 in the manufacturing method of the semiconductor device 1000 including a plurality of semiconductor chips.

### DESCRIPTION OF EXEMPLARY EMBODIMENTS

Hereinafter, embodiments of the present invention will be explained, but the following embodiments do not limit the invention according to the claims. In addition, not all of the combinations of features described in the embodiments are essential to the solution of the invention.

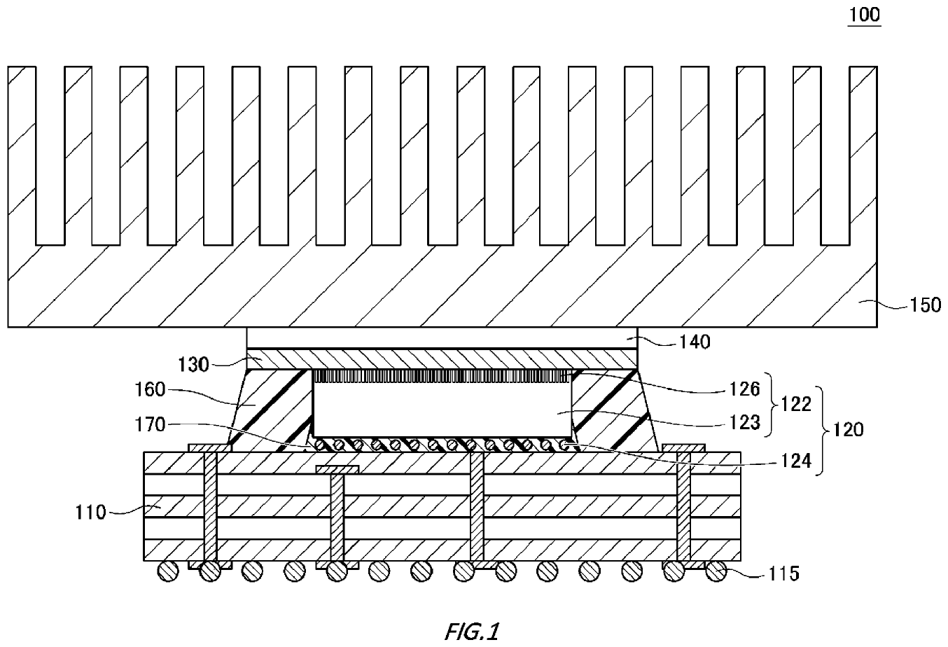

FIG. 1 shows a configuration of a semiconductor device 100 according to the present embodiment. The semiconductor device 100 includes a package substrate 110, a semiconductor chip 120, a thermal conductor 130, a TIM 140, a heatsink 150, the first underfill structure 160, and the second underfill structure 170.

The package substrate 110 has a mounting surface to which a substrate such as a printed circuit board mounting the semiconductor device 100 is electrically connected, and has a component mounting surface which mounts each component of the semiconductor device 100 such as the semiconductor chip 120. The package substrate 110 has a plurality of bumps 115 which are connected to a plurality of electrodes provided in the substrate which mounts the semiconductor device 100 on the mounting surface side. The plurality of bumps 115 may be formed of gold, copper, solder, or the like. In addition, the package substrate 110 may have one or more insulating layers and one or more wiring layers laminated alternatively and one or more conductive through vias which penetrate a plurality of layers. The package substrate 110 electrically connects the plurality of bumps 115 and the semiconductor chip 120 with being mediated by the one or more wiring layers and the one or more through vias. Note that, the package substrate 110 may mount a plurality of semiconductor chips 120. In this case, the package substrate 110 is an MCM (Multi-Chip Module).

The semiconductor chip 120 is mounted on the package substrate 110. The semiconductor chip 120 includes a chip substrate 122 and a plurality of bumps 124. In the chip substrate 122, a circuit is formed on the side of the mounting surface (which may also be shown as “the first surface”) closer to the package substrate 110. In other words, the semiconductor chip 120 is mounted on the package substrate 110 in an orientation such that the circuit surface faces down through flip chip packaging.

In the chip substrate 122, the transition structure 126 is integrated with the substrate body 123 on the second surface side which is opposite to the first surface. Here, the substrate body 123 of the chip substrate 122 is formed of a substrate material such as silicon. On the other hand, the transition structure 126 is obtained by causing the ratio of the substrate material of the chip substrate body 123 to be less than the ratio on the side of the first surface (or the central portion of the substrate body 123 where the circuit or the transition structure 126 is not provided) and adding a thermal conductive material having a higher thermal conductivity than the substrate material. In other words, in a region where the transition structure 126 is formed on the second surface side of the chip substrate 122, the chip substrate 122 has a structure having a higher ratio of the thermal conductive material compared to a region other than the circuit portion on the first surface side of the chip substrate 122. The thermal conductive material may be copper, polycrystalline diamond, or any other materials having a higher thermal conductivity than other substrate materials.

The transition structure 126 may have a structure where the thermal conductive material is filled into a plurality of trenches, a plurality of blind holes, or a pore structure formed on the second surface side of the chip substrate body 123. Here, the trench may have a vertical wall and may be in a tapered shape in which the width of the trench becomes narrower in the direction from the aperture on the second surface side to the depths. In addition, the blind hole may have a vertical wall and may be in a tapered shape in which the hole becomes narrower in the direction from the aperture on the second surface side to the depths. In addition, the transition structure 126 may have a structure where the substrate material and the thermal conductive material are arranged to be mixed in a periodic or aperiodic mosaic pattern.

The plurality of bumps 124 are arranged on the first surface side of the chip substrate 122 and connected to a plurality of electrodes provided in the component mounting surface of the package substrate 110. Each of the plurality of bumps 124 may be formed of gold, copper, solder, or the like.

The thermal conductor 130 is joined to the second surface of the semiconductor chip 120 and has a higher thermal conductivity than the substrate material of the substrate body 123. The thermal conductor 130 may be formed of copper, polycrystalline diamond, or any other materials having a higher thermal conductivity than the substrate material of the substrate body 123. The thermal conductor 130 may be of the same as or different from the thermal conductive material contained in the transition structure 126.

As shown in the present drawing, a projected area obtained by projecting the thermal conductor 130 in a direction vertical to the second surface of the semiconductor chip 120 (that is, an area of the thermal conductor 130 when the semiconductor device 100 is seen through from the top in the drawing) may be larger than the area of the second surface of the semiconductor chip 120. The thickness of the thermal conductor 130 may be from 1/10 to 100 times the thickness of the chip substrate 122.

The TIM 140 is provided between the thermal conductor 130 and the heatsink 150. The TIM 140 may be formed of metal and a metal alloy having a low melting temperature such as indium and galinstan, or may be high thermally conductive pasty grease or the like. The TIM 140 relaxes the stress between the thermal conductor 130 and the heatsink 150.

The heatsink 150 is provided on an opposite side of the surface of the thermal conductor 130 relative to the semiconductor chip 120. The heatsink 150 receives the heat generated in the semiconductor chip 120 with being mediated by the thermal conductor 130 and the TIM 140 and dissipates the heat to the outside of the semiconductor device 100. The heatsink 150 may have a structure with a large surface area in order to increase the efficiency of heat dissipation. For example, the heatsink 150 may have a structure where a plurality of fins (thin plates) are arrayed in parallel vertically to the surface that is in contact with the heatsink 150, or may have a structure in a pattern like a needle point holder for flower arrangement, where a plurality of poles are arrayed vertically to the surface that is in contact with the heatsink 150. The heatsink 150 may be formed of a relatively high thermally conductive material such as copper or aluminum. The semiconductor device 100 may include other heat dissipation members, such as a vapor chamber, a heat pump, and a heat exchanger, instead of the heatsink 150.

The first underfill structure 160 is provided in a space where the semiconductor chip 120 does not exist between the thermal conductor 130 and the package substrate 110. The first underfill structure 160 is formed by filling the first underfill material between the thermal conductor 130 and the package substrate 110. The first underfill material may be thermally curable resin including filler particles and may have a higher filler particle content than the second underfill material of the second underfill structure 170 which will be described below. The filler particle may be silica, alumina, or the like, and the size of the filler particle may be a few μm to tens of μm. The first underfill material may have a thermal expansion coefficient closer to that of the substrate material of the substrate body 123 when filler particles are included, compared to when a filler particle is not included.

The second underfill structure 170 is provided between the semiconductor chip 120 and the package substrate 110. The second underfill structure 170 is formed by filling the second underfill material between the semiconductor chip 120 and the package substrate 110. The second underfill material may be thermally curable resin. The second underfill material may include filler particles, similarly to the first underfill material.

According to the semiconductor device 100 above, providing the transition structure 126 obtained by reducing the ratio of the substrate material and increasing the ratio of the thermal conductive material in the semiconductor chip 120 allows the thermal stress generated on the contact surface of the semiconductor chip 120 and the thermal conductor 130 to be relaxed, and allows the chip substrate 122 and the thermal conductor 130 to be joined without being mediated by the TIM. In addition, the semiconductor device 100 with such a transition structure 126 allows the heat generated in the circuit to be transferred from the substrate material of the substrate body 123 to the thermal conductive material highly efficiently and to be conducted to the thermal conductor 130.

In addition, the semiconductor device 100 allows the heat from the second surface of the semiconductor chip 120 to diffuse in a horizontal direction of FIG. 1 through the thermal conductor 130 and allows the heat to be dissipated to the heatsink 150 in contact with the thermal conductor 130 with a wider area than the second surface of the semiconductor chip 120. In this way, the semiconductor device 100 allows more heat to be dissipated from the semiconductor chip 120 to the heatsink 150 compared to when the heatsink 150 is connected to the second surface of the substrate body 123 with being mediated by the TIM.

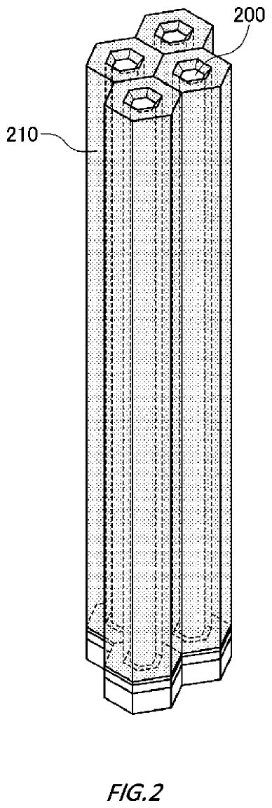

FIG. 2 shows a perspective view of the first example of the transition structure 126 according to the present embodiment. The lower side of the paper surface of the present drawing is the first surface side of the chip substrate 122, and the upper side of the paper surface is the second surface side of the chip substrate 122. In the example of the present drawing, for each region in a regular hexagonal shape, which is obtained by segmenting the second surface into hexagonal grid patterns, the substrate body 123 has a structure where the substrate material 200 remains in the central portion of each region and the substrate material 200 is removed to a certain depth (approximately 100 μm in the example of the present drawing) by etching or the like and the thermal conductive material 210 is filled in the portion other than the central portion. In the example of the present drawing, a columnar portion in a regular hexagonal shape of the substrate material 200 is formed in the central portion of each region.

In this manner, the transition structure 126 may employ a structure where the thermal conductive material 210 is embedded around the columnar portions of the substrate material 200 arrayed in a regular manner such as a lattice pattern (such as a triangular grid, a square grid, and a hexagonal grid), for example. Instead of this, the transition structure 126 may employ a structure where the thermal conductive material 210 is embedded around columnar portions of the substrate material 200 arranged in an irregular manner. Here, the columnar portion of the substrate material 200 may have a wall vertical to the second surface, and the cross-sectional plane parallel to the second surface may have a shape of a polygon, a regular polygon, a circle, or an oval, or any other shapes. In addition, the columnar portion of the substrate material 200 may be in a tapered shape in which the cross-sectional area becomes wider in the direction from the second surface side to the depths. In addition, on the contrary to the above, the transition structure 126 may employ a structure where the substrate material 200 remains in the portion other than the central portion of each region, which is obtained by segmenting the second surface of the substrate body 123 in a regular or irregular manner, and the substrate material 200 is removed to a certain depth by etching or the like and the thermal conductive material 210 is filled in the central portion. In addition, on the upper side of the paper surface, the thermal conductor 130 exists. Continuing the transition structure 126 on the side of the thermal conductor 130 may be intended by providing appropriate pores on the surface on which the thermal conductor 130 is in contact with the transition structure 126. The pore provided on the thermal conductor 130 may be a columnar pore having a wall vertical to the second surface, and the cross-sectional plane parallel to the second surface may have a shape of a polygon, a regular polygon, a circle, or an oval, or any other shapes. In addition, the pore provided on the thermal conductor 130 may be in a tapered shape.

In the chip substrate 122 having the transition structure 126 on the second surface side shown above, while, in a region closer to the first surface than a region in which the transition structure 126 is formed, the ratio of the substrate material on the cross-sectional plane in the plane direction is 100%, in the region in which the transition structure 126 is formed, the ratio of the substrate material on the cross-sectional plane in the plane direction is less than 100% (for example, 10 to 90%, 25 to 75%, 40 to 60%, or the like) and the ratio of the thermal conductive material is more than 0% (for example, 90 to 10%, 75 to 25%, 60 to 40%, or the like). The transition structure 126 is joined and fixed to the thermal conductor 130 on the second surface side of the chip substrate 122. Here, when the coefficient of thermal expansion of the thermal conductive material of the thermal conductor 130 is closer to the coefficient of thermal expansion of the thermal conductive material of the transition structure 126 than the coefficient of thermal expansion of the substrate material, the transition structure 126 has the coefficient of thermal expansion between the coefficient of thermal expansion of the substrate body 123 of the region in which the transition structure 126 is not formed and the coefficient of thermal expansion of the thermal conductor 130. Accordingly, providing the transition structure 126 in the chip substrate 122 allows the semiconductor device 100 to relax the thermal stress between the chip substrate 122 and the thermal conductor 130 and to join and fix them directly without being mediated by the TIM.

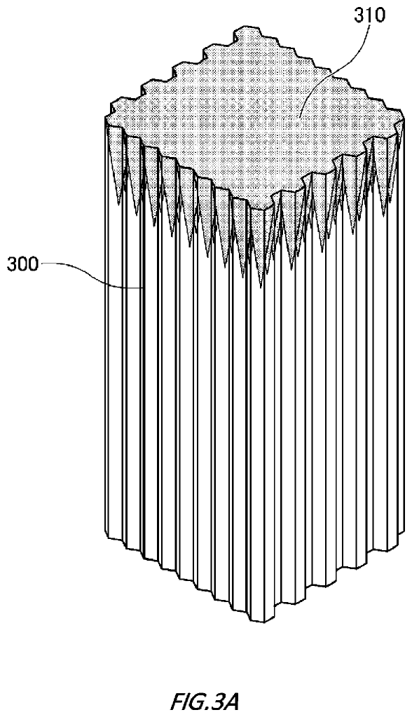

FIG. 3A shows a perspective view of the second example of the transition structure 126 according to the present embodiment. FIG. 3B shows a cross-sectional view of the second example of the transition structure 126 according to the present embodiment. The lower side of the paper surface of the present drawing is the first surface side of the chip substrate 122, and the upper side of the paper surface is the second surface side of the chip substrate 122. In the example of the present drawing, the substrate body 123 has a plurality of blind holes with a certain depth (approximately 50 μm in the example of the present drawing) formed in a lattice pattern on the second surface and employs a structure where the thermal conductive material 310 is filled into the blind holes. In the example of the present drawing, the blind hole is in a regular hexagonal shape with the one side length of approximately 5 μm (a distance between opposing vertices of approximately 9 μm) and has a dipping structure where the cross-sectional area becomes smaller in the direction from the second surface side to the depths. In other words, in the direction from the second surface side to the first surface side, the ratio (density) of the thermal conductive material 310 decreases and the ratio (density) of the substrate material 300 increases.

In this manner, the transition structure 126 may employ a structure where the thermal conductive material 310 is embedded inside the trenches arrayed in a regular or irregular manner, for example, in a lattice pattern or the like (such as a triangular grid, a square grid, and a hexagonal grid). Here, the trenches may be in contact, or may not be in contact. In addition, the trench may have the cross-sectional plane parallel to the second surface in a shape of a polygon, a regular polygon, a circle, or an oval, or any other shapes. The trenches may have a wall vertical to the second surface and may have a fixed cross-sectional area. The trench may have a dipping structure where the cross-sectional area becomes smaller in the direction from the second surface side to the depths, and may have a different shape of cross-sectional plane in the middle.

Providing the transition structure 126 shown above allows the semiconductor device 100 to relax the thermal stress generated between the chip substrate 122 and the thermal conductor 130 and to join and fix them directly without being mediated by the TIM, as described with reference to FIG. 2.

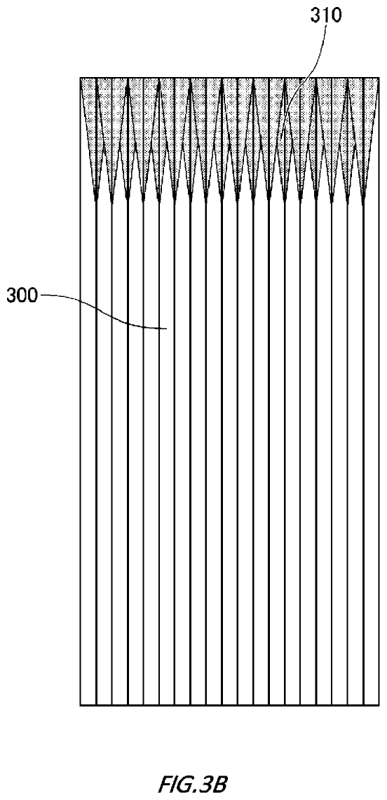

FIG. 4 shows an example of a layer structure formed between the substrate material and the thermal conductive material in the transition structure 400. The transition structure 400 may be used as the transition structure 126 shown in FIG. 1 to FIG. 3B. The transition structure 400 shows an example of the layer structure of a portion where the thermal conductive material is filled into one trench or blind hole, or the like formed in the substrate body 123. The transition structure 400 in the present drawing has a region substantially 100% of which is of a thermal conductive material 420, not including a substrate material 410 on the cross-sectional plane in a plane direction, on the surface of the second surface 405 or in a region excluding coating on the surface.

The transition structure 400 has a diffusion prevention layer 430 which prevents the thermal conductive material 420 from diffusing to the side of the substrate material 410, on a surface of a plurality of trenches, a plurality of blind holes, a pore structure, or the like on the side of the second surface 405 of the substrate body 123, that is, the surface of the substrate material 410 which forms the these shapes on the second surface side of the substrate body 123 and thus is exposed. The diffusion prevention layer 430 may contain at least one of Ta, TaN, SiO₂, or Si₃N₄.

In the example of the present drawing, the diffusion prevention layer 430 employs a multi-layer structure having an insulating layer 432 and a barrier metal layer 434. The insulating layer 432 may be formed between the substrate material 410 and the barrier metal layer 434. The insulating layer 432 may have a thickness of 50 nm to 100 nm, for example. The insulating layer 432 may contain SiO₂, Si₃N₄, or other insulating materials. Providing the insulating layer 432 allows the circuit on the first surface side of the semiconductor chip 120 and the thermal conductor 130 to be electrically insulated from each other, which can cause an electric potential of the circuit to be stable.

The barrier metal layer 434 may be formed between the thermal conductive material 420 and the insulating layer 432. The barrier metal layer 434 may have a thickness of 20 nm to 100 nm, for example. The barrier metal layer 434 may contain at least one of Ta or TaN. Providing the barrier metal layer 434 allows the thermal conductive material 420 to be prevented from diffusing to the side of the substrate material 410.

The transition structure 400 may have an oxidation prevention layer 440 on the side of the second surface 405 of the substrate body 123. The oxidation prevention layer 440 may have a thickness of 20 nm to 100 nm, for example. The oxidation prevention layer 440 may contain a material, such as Ni, which is less likely to be oxidized than the thermal conductive material 420. The oxidation prevention layer 440 is responsible for preventing the surface of the transition structure 400 from being oxidized and also facilitating joining of the transition structure 400 and the thermal conductor 130.

FIG. 5 shows a configuration of the vapor chamber 500. The semiconductor device 100 may use the vapor chamber 500 as the thermal conductor 130 instead of a board-shaped thermal conductive plate as shown in FIG. 1. The vapor chamber 500 has a hollow structure and has a coolant fluid 540 inside. The inside of the vapor chamber 500 may be a vacuum. The vapor chamber 500 has the first thermal conductor component 510, the second thermal conductor component 520, a protrusion portion 530, and the coolant fluid 540.

The first thermal conductor component 510 only has part of the inner wall surface of the vapor chamber 500. In the example of the present drawing, the first thermal conductor component 510 has an inner wall surface corresponding to the bottom surface and the side surfaces of a container containing the coolant fluid 540. The first thermal conductor component 510 may have most of the inner wall surface of the container containing the coolant fluid 540. The first thermal conductor component 510 may be formed of a relatively high thermally conductive material, such as copper, aluminum, or the like. The first thermal conductor component 510 may be formed of a material which is easy to be joined to the thermal conductive material in the transition structure, for example, a material same as the thermal conductive material in the transition structure.

The second thermal conductor component 520 has other part of the inner wall surface of the vapor chamber 500. In the example of the present drawing, the second thermal conductor component 520 has an inner wall surface corresponding to the upper surface of the container containing the coolant fluid 540. The second thermal conductor component 520 may be a thin plate. The second thermal conductor component 520 is joined to the first thermal conductor component 510 to form the hollow structure of the vapor chamber 500. The second thermal conductor component 520 may have a plurality of protrusion portions 530 on the side of the inner wall surface of the coolant fluid 540. The second thermal conductor component 520 may be formed of a relatively high thermally conductive material, such as copper, aluminum, or the like. At least some of the plurality of protrusion portions 530 may extend to the bottom surface of the first thermal conductor component 510.

The coolant fluid 540 is encapsulated at the bottom in the hollow structure of the vapor chamber 500. The coolant fluid 540 is liquid such as pure water. The coolant fluid 540 is heated with a heat source in contact with the first thermal conductor component 510, is vaporized into a gas and spreads in a space, then is cooled down, becomes liquid back again, and returns to the bottom through capillary action by the protrusion portion 530.

Note that, the semiconductor device 100 may use a vapor chamber having a different structure instead of the vapor chamber 500 in the present drawing. For example, a vapor chamber may have a component in a container shape having an inlet through which the coolant fluid 540 is injected, instead of the first thermal conductor component 510, as a thermal conductor component only having part of the inner wall surface of the vapor chamber and have a component to be a lid of the inlet, instead of the second thermal conductor component 520, as a component having other part of the inner wall surface of the vapor chamber. In this case, the component to be the lid of the inlet may not necessarily be highly thermally conductive.

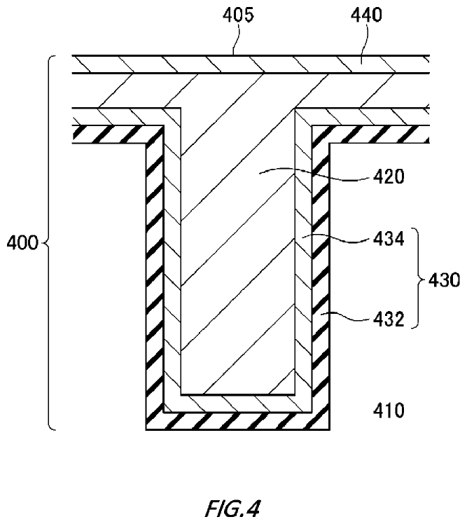

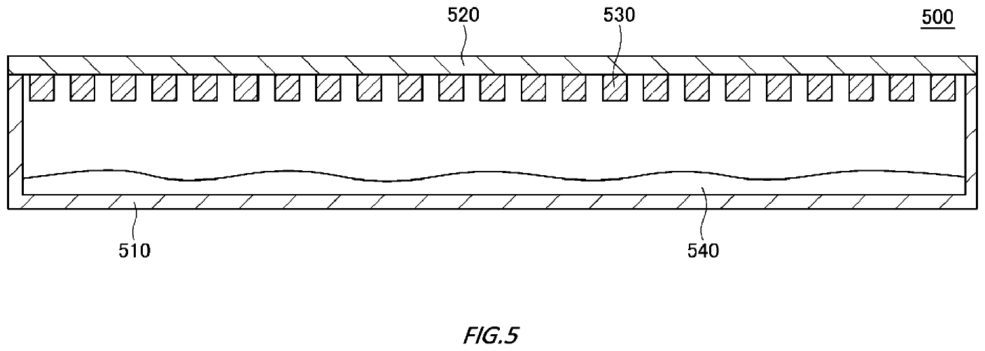

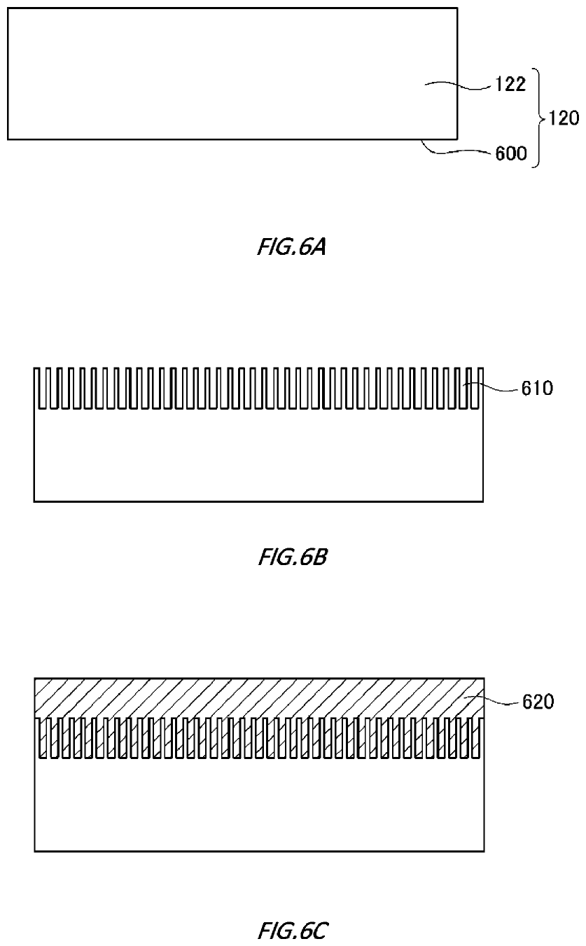

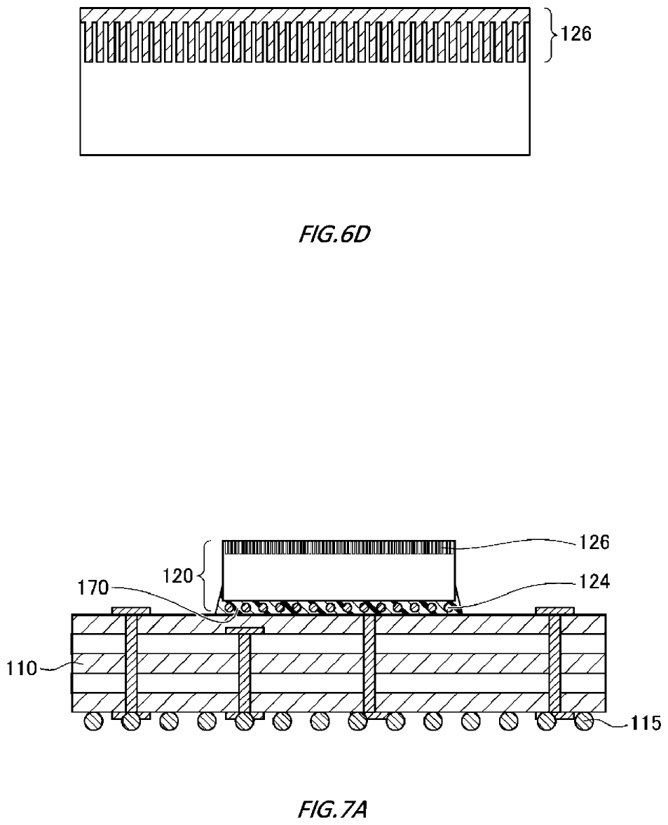

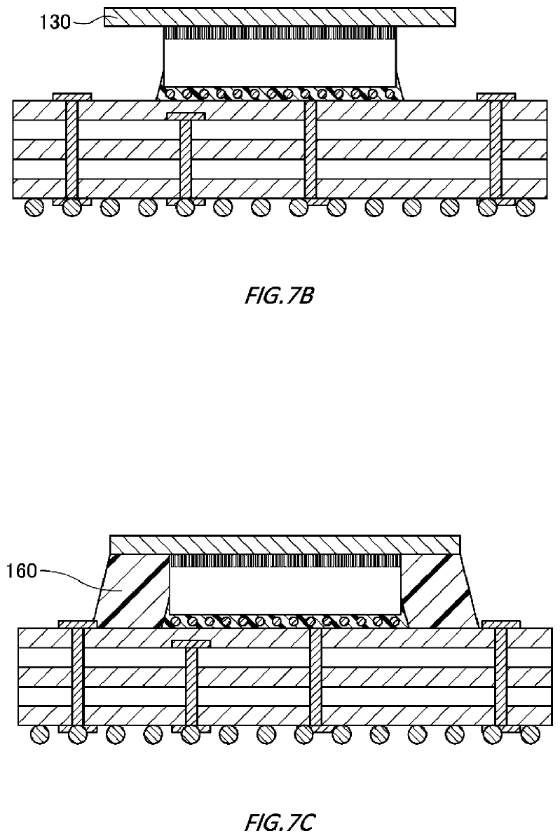

FIG. 6A to FIG. 6D and FIG. 7A to FIG. 7C show a manufacturing method of the semiconductor device 100 according to the present embodiment. The manufacturing method of the semiconductor device 100 includes manufacturing processes of the semiconductor chip 120 itself including forming the transition structure 126 shown in FIG. 6A to FIG. 6D, and manufacturing processes of the semiconductor device 100 shown in FIG. 7A to FIG. 7C.

FIG. 6A shows the stage of manufacturing the semiconductor chip 120 in the manufacturing method of the semiconductor device 100 according to the present embodiment. In the present process, a circuit 600 is formed on the first surface side (the lower side of the paper surface) of the chip substrate 122 (that is, a region to be the chip substrate 122 in FIG. 1 after the dicing of the semiconductor chip 120 in the wafer) in a wafer state formed of a substrate material such as silicon, to manufacture the semiconductor chip 120 (a structure to be the semiconductor chip 120 in FIG. 1 after the dicing).

FIG. 6B shows the stage of forming a trench 610 in the manufacturing method of the semiconductor device 100 according to the present embodiment. In the present process, a plurality of trenches 610 are formed by selective etching, either dry etching or wet etching, or the like, on the second surface side (the upper side of the paper surface), which is opposite to the first surface of the chip substrate 122. The depth of the trench 610 may approximately be the thickness of the thermal conductor 130 to be joined later.

FIG. 6C shows the stage of filling a thermal conductive material 620 in the manufacturing method of the semiconductor device 100 according to the present embodiment. The thermal conductive material 620 is filled into the plurality of trenches 610. For example, after a thermal conductive material layer to be a seed layer is formed by sputtering, the thermal conductive material 620 is filled by using electroplating. Filling the thermal conductive material 620 only requires a thickness of approximately the half of the width of the trench 610. Before filling the thermal conductive material 620, a diffusion prevention layer 430 which prevents the thermal conductive material from diffusing may be formed on the surface of the plurality of trenches 610.

FIG. 6D shows the stage of forming the transition structure 126 in the manufacturing method of the semiconductor device 100 according to the present embodiment. Mirror polishing is performed on the surface of the thermal conductive material 620 in a chemical mechanical polishing method (CMP method) or the like. Note that, the oxidation prevention layer 440 may be formed on the surface of the transition structure 126. In this way, the transition structure 126 obtained by causing the ratio of the substrate material of the chip substrate body to be less than the ratio on the first surface side and adding the thermal conductive material having a higher thermal conductivity than the substrate material can be integrated on the second surface side which is opposite to the first surface of the chip substrate.

Note that, according to the manufacturing method shown in FIG. 6A to FIG. 6D, by forming the plurality of trenches 610 on the second surface side of the substrate body 123 in the semiconductor chip 120 and filling the thermal conductive material 620 into the plurality of trenches 610, a chip substrate 122 with a transition structure 126 being integrally formed can be manufactured, wherein the chip substrate 122 includes a structural portion of the substrate material which is integrated with the original substrate body 123 and a structural portion of the thermal conductive material 620 filled into the plurality of trenches 610. Instead of this, in order to integrate the transition structure 126 on the second surface side of the semiconductor chip 120, a substrate which has the transition structure 126 manufactured in a similar method to FIG. 6B to FIG. 6D but does not have the circuit 600 may be inseparably bonded, through adhering using an adhesive layer or through joining using plasma activation or the like, to the second surface of the chip substrate 122 on which the circuit 600 is formed on the first surface side in the process shown in FIG. 6A.

FIG. 7A shows the stage of mounting a diced semiconductor chip 120 on the package substrate 110 in the first embodiment of the manufacturing method of the semiconductor device 100 according to the present embodiment. In the present process, first, the semiconductor chip 120 in a wafer state shown in FIG. 6D is diced, and a bump 124 is formed for each electrode on the circuit surface. Then, the package substrate 110 which has an electrode pad to be connected to each bump 124 of the semiconductor chip 120 on the side of the component mounting surface, has the plurality of bumps 115 on the mounting surface side, and has the wiring layer to electrically connect each electrode pad and the corresponding bump 115 is prepared. Then, the semiconductor chip 120 is mounted on the component mounting surface of the package substrate 110. Each bump 124 of the semiconductor chip 120 is joined to the corresponding electrode pad on the component mounting surface of the package substrate 110. In addition, the second underfill material may be injected between the package substrate 110 and the semiconductor chip 120 to provide the second underfill structure 170.

FIG. 7B shows the stage of joining the semiconductor chip 120 and the thermal conductor 130 in the first embodiment of the manufacturing method of the semiconductor device 100 according to the present embodiment. In the process of the present drawing, the surfaces of the semiconductor chip 120 and the thermal conductor 130 are activated by plasma treatment, and then the thermal conductor 130 is joined to the second surface of the semiconductor chip 120, that is, the surface on which the transition structure 126 is formed. The thermal conductor 130 may have an alignment mark on the surface to which the semiconductor chip 120 is joined. This allows the thermal conductor 130 and the semiconductor chip 120 to be aligned using the alignment mark of the thermal conductor 130 in joining the thermal conductor 130 to the second surface of the semiconductor chip 120. The thermal conductor 130 may provide various stamps on a surface on a side facing the semiconductor chip 120 and not contacting with the semiconductor chip 120, for example a stamp describing information of a thermal conductor member. This facilitates a manufacturer of the semiconductor device 100 or the manufacture device selecting a right component as the thermal conductor 130 by visual observation or mechanical reading.

FIG. 7C shows the stage of forming the first underfill structure 160 in the first embodiment of the manufacturing method of the semiconductor device 100 according to the present embodiment. Optionally, the first underfill structure 160 is formed by filling the first underfill material into a space in which the semiconductor chip 120 does not exist between the thermal conductor 130 and the package substrate 110 joined to the semiconductor chip 120. Injecting the first underfill material into the space may be performed with being mediated by a through hole provided in the thermal conductor 130.

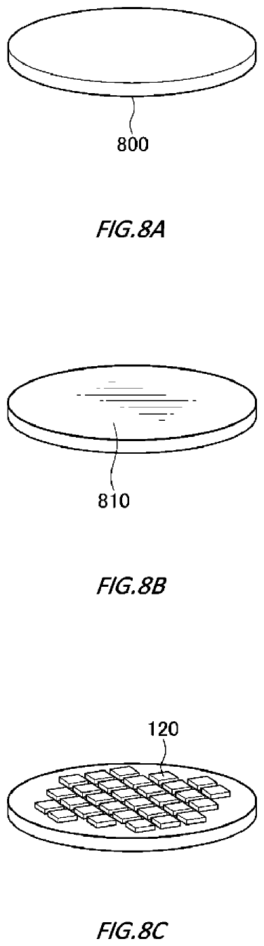

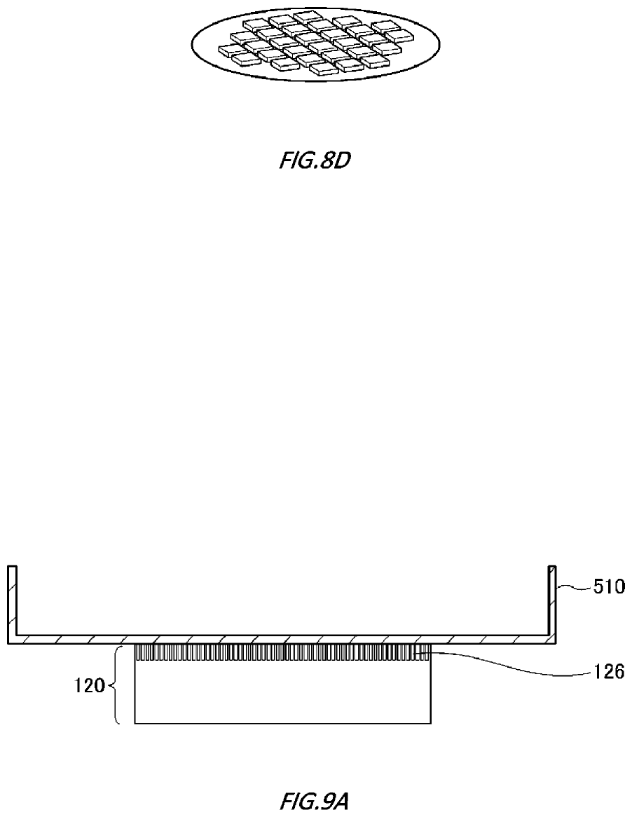

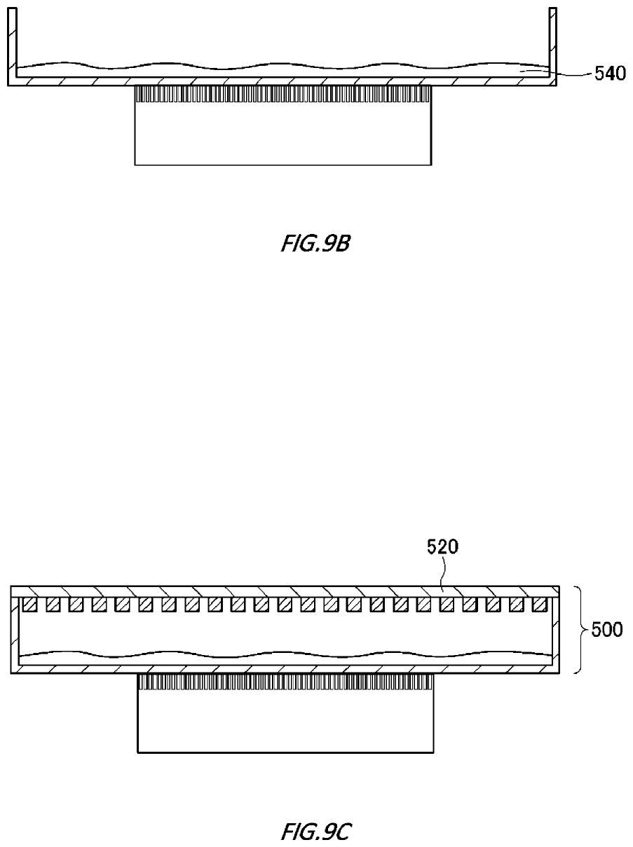

FIG. 8A shows a structure of a carrier substrate 800 in the second embodiment of the manufacturing method of the semiconductor device 100 according to the present embodiment. In the present process, the carrier substrate 800 is prepared. The carrier substrate 800 may be in a wafer shape or may be in a rectangular shape. The carrier substrate 800 may have a board-shaped rigid body of silicon, glass, or others, and may be a board-shaped substrate having flexibility, such as a plastic film.

FIG. 8B shows the stage of forming a thermal conductive layer 810 in the second embodiment of the manufacturing method of the semiconductor device 100 according to the present embodiment. In the present process, the thermal conductive layer 810 is formed on the surface of the carrier substrate 800. In the present process, for example, on the surface of the carrier substrate 800, an adhesive is applied and then a thin-film thermal conductive layer 810 may be stuck. The thermal conductive layer 810 is the thermal conductor 130 shown in FIG. 1. The thermal conductive layer 810 may have a thickness of approximately 0.2 mm, for example.

FIG. 8C shows the stage of joining the thermal conductive layer 810 and the semiconductor chip 120 in the second embodiment of the manufacturing method of the semiconductor device 100 according to the present embodiment. In the present process, the surfaces of the thermal conductive layer 810 and the semiconductor chip 120 are activated by plasma treatment, and then the second surfaces of diced ones of the plurality of semiconductor chips 120 are joined to the thermal conductive layer 810 on the surface of the carrier substrate 800. The semiconductor chip 120 may be joined spaced apart such that neighboring semiconductor chips 120 do not contact with each other. This allows the projected area obtained by projecting the thermal conductor 130 in a direction vertical to the second surface of the semiconductor chip 120 to be larger than the area of the second surface of the semiconductor chip 120 after the dicing described below.

FIG. 8D shows the stage of separating the thermal conductive layer 810 from the carrier substrate 800 in the second embodiment of the manufacturing method of the semiconductor device 100 according to the present embodiment. In the present process, the thermal conductive layer 810 to which the plurality of semiconductor chips 120 are joined is diced by being cut between the semiconductor chips 120 and being separated from the carrier substrate 800. In this way, the carrier substrate 800 is left with the thermal conductive layer 810 remaining only in a region where the semiconductor chip 120 has not been joined and not separated. Note that, if a plastic film is used as the carrier substrate 800, the carrier substrate 800 may be cut together with the thermal conductive layer 810 when the thermal conductive layer 810 is cut. A mold may be filled between the semiconductor chip 120 and the semiconductor chip 120. In this case, the mold may be part of the first underfill structure 160.

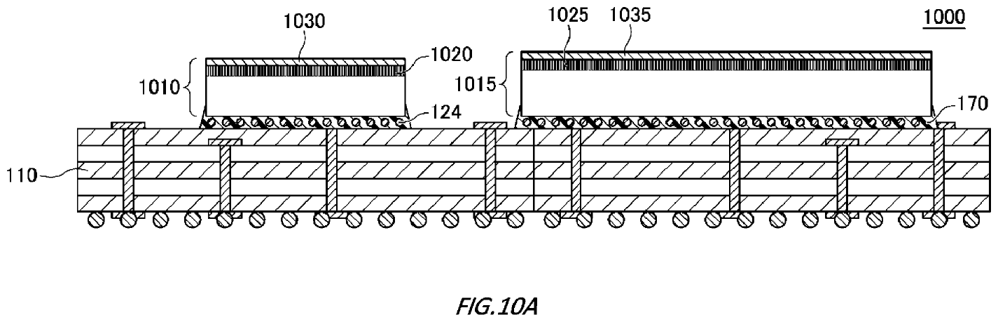

FIG. 9A shows the stage of joining the semiconductor chip 120 and the first thermal conductor component 510 in the method of joining the semiconductor chip 120 and the vapor chamber 500. In the present process, the surfaces of the first thermal conductor component 510 and the semiconductor chip 120 are activated by plasma treatment, and the first thermal conductor component 510 is joined to the second surface of the semiconductor chip 120.

FIG. 9B shows the stage of injecting the coolant fluid 540 into the first thermal conductor component 510 in the method of joining the semiconductor chip 120 and the vapor chamber 500. The present process is performed after heating accompanying reflow or thermal curing of the semiconductor device including the semiconductor chip and the thermal conductor although this is not depicted.

FIG. 9C shows the stage of joining the first thermal conductor component 510 and the second thermal conductor component 520 in the method of joining the semiconductor chip 120 and the vapor chamber 500. In the present process, a sealed space to be the vapor chamber 500 is formed by joining the first thermal conductor component 510 and the second thermal conductor component 520 while vacuumizing the hollow space between the first thermal conductor component 510 and the second thermal conductor component 520.

Here, if a heating process is performed after the coolant fluid 540 is injected into the sealed space of the vapor chamber 500 instead of the above-described joining method of the vapor chamber 500, there is a possibility that the coolant fluid 540 is excessively heated and completely boiled, the sealed space is caused to have high pressure, and the vapor chamber 500 bursts. According to the joining method of the vapor chamber 500 shown above, injecting the coolant fluid 540 into the first thermal conductor component 510 to join the second thermal conductor component 520 after a heating process such as reflow required to manufacture the semiconductor device 100 can prevent the vapor chamber 500 from bursting in the heating process.

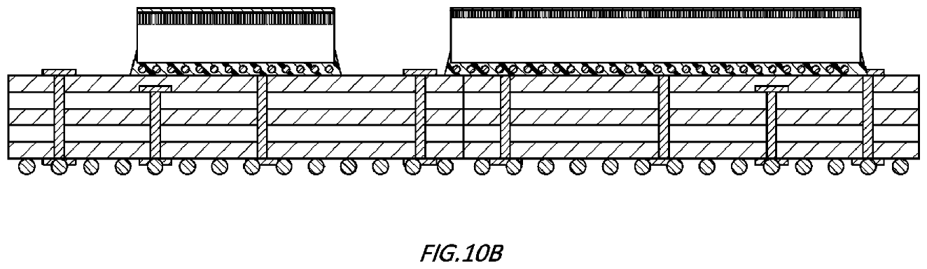

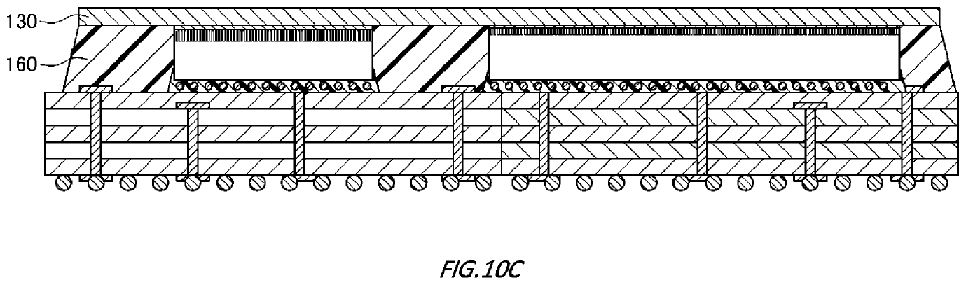

FIG. 10A shows the stage of mounting the first semiconductor chip 1010 and the second semiconductor chip 1015 on the package substrate 110 in the manufacturing method of a semiconductor device 1000 including a plurality of semiconductor chips. The semiconductor device 1000 is a modification of the one shown in FIG. 1, and descriptions except for differences are omitted hereinafter. The semiconductor device 1000 is a multi-chip module (MCM) mounting a plurality of semiconductor chips (the first semiconductor chip 1010 and the second semiconductor chip 1015 in the example of the present drawing).

In the present process, first, the first semiconductor chip 1010 in which the first transition structure 1020 is formed, the second semiconductor chip 1015 in which the second transition structure 1025 is formed, and the package substrate 110 are prepared. The first semiconductor chip 1010 and the second semiconductor chip 1015 may have similar structures to the semiconductor chip 120 shown in FIG. 1. On the first semiconductor chip 1010 and the second semiconductor chip 1015, circuits having the same function may be formed, or circuits having a function different from each other may be formed.

The first transition structure 1020 includes a margin region 1030 formed needlessly on the first surface side of the chip substrate body of the first semiconductor chip 1010. Similarly, the second transition structure 1025 includes a margin region 1035 formed in a thick manner on the first surface side of the chip substrate body of the second semiconductor chip 1015. The margin region 1030 and the margin region 1035 may be regions having the ratio of the thermal conductive material being 100% and the ratio of the substrate material 0%, or may be a region having the ratio of the substrate material being more than 0% and less than 100%.

In the present process, the first semiconductor chip 1010 and the second semiconductor chip 1015 are mounted on the package substrate 110. Mounting the first semiconductor chip 1010 and the second semiconductor chip 1015 on the package substrate 110 may be performed with being mediated by the bump 124. The second underfill structure 170 may be provided by filling the second underfill material between the package substrate 110, and the first semiconductor chip 1010 and the second semiconductor chip 1015.

FIG. 10B shows the stage of aligning the heights of the first transition structure 1020 and the second transition structure 1025 in the manufacturing method of the semiconductor device 1000 including a plurality of semiconductor chips. Here, the heights of the first surface of the first semiconductor chip 1010 and the first surface of the second semiconductor chip 1015 relative to the component mounting surface of the package substrate 110 may be slightly different under the influence of an error in size of the bump 124, an error in thickness of the chip substrate bodies of the first semiconductor chip 1010 and the second semiconductor chip 1015, an error in thickness of the first transition structure 1020 and the second transition structure 1025, or the like. In the present process, the heights of the first transition structure 1020 and the second transition structure 1025 relative to the package substrate 110 are aligned by polishing the first transition structure 1020 and the second transition structure 1025 from the second surface side of the first semiconductor chip 1010 and the second semiconductor chip 1015 in a CMP method or the like. In this process, at least part of the margin region 1030 and the margin region 1035 of the first transition structure 1020 and the second transition structure 1025 may be polished.

FIG. 10C shows the stage of joining the thermal conductor 130 to the first semiconductor chip 1010 and the second semiconductor chip 1015 in the manufacturing method of the semiconductor device 1000 including a plurality of semiconductor chips. The surfaces of the first semiconductor chip 1010, the second semiconductor chip 1015, and the thermal conductor 130 are activated by plasma treatment, and then one thermal conductor 130 is joined to the second surface of the first semiconductor chip 1010 and the second surface of the second semiconductor chip 1015. Optionally, the first underfill structure 160 may be formed by filling the first underfill material into a space in which the first semiconductor chip 1010 and the second semiconductor chip 1015 does not exist between the package substrate 110 and the thermal conductor 130.

According to the manufacturing method above, in manufacturing the semiconductor device 1000 including a plurality of semiconductor chips such as the first semiconductor chip 1010 and the second semiconductor chip 1015, a process of aligning the heights of the transition structures of the plurality of semiconductor chips (such as the first transition structure 1020 and the second transition structure 1025) is included, which can prevent connection failure between each semiconductor chip and the thermal conductor 130.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

100: semiconductor device, 110: package substrate, 115: bump, 120: semiconductor chip, 122: chip substrate, 123: substrate body, 124: bump, 126: transition structure, 130: thermal conductor, 140: TIM, 150: heatsink, 160: first underfill structure, 170: second underfill structure, 200: substrate material, 210: thermal conductive material, 300: substrate material, 310: thermal conductive material, 400: transition structure, 405: second surface, 410: substrate material, 420: thermal conductive material, 430: diffusion prevention layer, 432: insulating layer, 434: barrier metal layer, 440: oxidation prevention layer, 500: vapor chamber, 510: first thermal conductor component, 520: second thermal conductor component, 530: protrusion portion, 540: coolant fluid, 600: circuit, 610: trench, 620: thermal conductive material, 800: carrier substrate, 810: thermal conductive layer, 1000: semiconductor device, 1010: first semiconductor chip, 1015: second semiconductor chip, 1020: first transition structure, 1025: second transition structure, 1030: margin region, 1035: margin region.

What is claimed is:

1. A semiconductor device, comprising:
a semiconductor chip where a circuit is formed on a side of a first surface of a chip substrate and a transition structure is integrated on a side of a second surface which is opposite to the first surface of the chip substrate, wherein the transition structure is obtained by causing a ratio of a substrate material of a chip substrate body to be less than a ratio of the substrate material on the side of the first surface and adding a thermal conductive material which has a higher thermal conductivity than the substrate material; and
a thermal conductor which is joined to the second surface of the semiconductor chip and has a higher thermal conductivity than the substrate material.

2. The semiconductor device according to claim 1, wherein a projected area obtained by projecting the thermal conductor in a direction vertical to the second surface of the semiconductor chip is larger than an area of the second surface of the semiconductor chip.

3. The semiconductor device according to claim 1, wherein the transition structure has a structure where the thermal conductive material is filled into a plurality of trenches, a plurality of blind holes, or a pore structure formed on the side of the second surface of the chip substrate body.

4. The semiconductor device according to claim 3, wherein the transition structure comprises a diffusion prevention layer which prevents diffusion of the thermal conductive material, on a surface of the plurality of trenches, the plurality of blind holes, or the pore structure, before filling the thermal conductive material.

5. The semiconductor device according to claim 4, wherein the diffusion prevention layer contains at least one of Ta, TaN, SiO₂, or Si₃N₄.

6. The semiconductor device according to claim 1, wherein the transition structure does not contain the substrate material on a surface of the second surface.

7. The semiconductor device according to claim 1, further comprising:
a package substrate which mounts the semiconductor chip; and
a first underfill structure where a first underfill material is filled into a space in which the semiconductor chip does not exist between the thermal conductor and the package substrate.

8. The semiconductor device according to claim 7, further comprising: a second underfill structure where a second underfill material is filled between the semiconductor chip and the package substrate.

9. The semiconductor device according to claim 8, wherein the first underfill material has a higher filler particle content than the second underfill material.

10. The semiconductor device according to claim 1, wherein the thermal conductor comprises a vapor chamber.

11. The semiconductor device according to claim 1, further comprising: a heatsink provided on an opposite side of a surface of the thermal conductor relative to the semiconductor chip.

12. A manufacturing method of a semiconductor device, comprising:
integrating, in a semiconductor chip where a circuit is formed on a side of a first surface of a chip substrate, a transition structure on a side of a second surface which is opposite to the first surface of the chip substrate, wherein the transition structure is obtained by causing a ratio of a substrate material of a chip substrate body to be less than a ratio of the substrate material on the side of the first surface and by adding a thermal conductive material which has a higher thermal conductivity than the substrate material; and
joining a thermal conductor which has a higher thermal conductivity than the substrate material to the second surface of the semiconductor chip.

13. The manufacturing method according to claim 12, wherein forming the transition structure comprises:
forming a plurality of trenches, a plurality of blind holes, or a pore structure on the side of the second surface of the chip substrate body; and
filling the thermal conductive material into the plurality of trenches, the plurality of blind holes, or the pore structure.

14. The manufacturing method according to claim 13, wherein forming the transition structure comprises: forming a diffusion prevention layer which prevents diffusion of the thermal conductive material, on a surface of the plurality of trenches, the plurality of blind holes, or the pore structure, before filling the thermal conductive material.

15. The manufacturing method according to claim 12, comprising:
mounting the semiconductor chip on a package substrate; and
filling a first underfill material into a space in which the semiconductor chip does not exist between the thermal conductor, which is joined to the semiconductor chip, and the package substrate.

16. The manufacturing method according to claim 15, wherein in filling the first underfill material, the first underfill material is injected into the space via a through hole provided in the thermal conductor.

17. The manufacturing method according to claim 12, wherein
the thermal conductor has an alignment mark on a surface to which the semiconductor chip is to be joined, and
in joining the thermal conductor to the second surface of the semiconductor chip, the alignment mark of the thermal conductor is used to align the thermal conductor and the semiconductor chip.

18. The manufacturing method according to claim 12, comprising bonding a thermal conductive layer used as the thermal conductor to a surface of a carrier substrate, wherein
joining the thermal conductor to the second surface of the semiconductor chip comprises:
joining a plurality of second surfaces each of which is the second surface of the semiconductor chip, to the thermal conductive layer on the surface of the carrier substrate;
separating, from the carrier substrate, the thermal conductive layer, to which a plurality of semiconductor chips each of which is the semiconductor chip are joined; and
dicing the thermal conductive layer, to which the plurality of semiconductor chips are joined, by cutting the thermal conductive layer between the plurality of semiconductor chips.

19. The manufacturing method according to claim 15, wherein joining the thermal conductor to the second surface of the semiconductor chip comprises:
joining, to the second surface of the semiconductor chip, a thermal conductor component only having part of an inner wall surface of a vapor chamber to be included by the thermal conductor; and
forming a sealed space to be the vapor chamber by joining a component having other part of the inner wall surface of the vapor chamber to the thermal conductor component after heating accompanying reflow or thermal curing of a semiconductor device comprising the semiconductor chip and the thermal conductor.

20. The manufacturing method according to claim 15, comprising:
mounting, on a package substrate, a first semiconductor chip being the semiconductor chip in which a first transition structure being the transition structure is formed and a second semiconductor chip being the semiconductor chip in which a second transition structure being the transition structure is formed;
aligning heights of the first transition structure and the second transition structure relative to the package substrate by polishing the first transition structure and the second transition structure from a side of the second surface of the first semiconductor chip and the second semiconductor chip; and
joining one thermal conductor being the thermal conductor to the second surface of the first semiconductor chip and the second surface of the second semiconductor chip.
